(19) United States
(12) Patent Application Publication
(10) Pub. No.: US 2001/0038309 A1
(43) Pub. Date: Nov. 8, 2001

(54) Filter circuit

(75) Inventor: Frank Hagemeyer, Wedemark (DE)

Correspondence Address: OLDHAM & OLDHAM CO, TWIN OAKS ESTATE, 1225 W MARKET STREET, AKRON, OH, 44313, US

(73) Assignee: Sennheiser Electronic GmbH & Co. KG

(21) Appl. No.: 09/789,288

(22) Filed: Feb. 20, 2001

(30) Foreign Application Priority Data
Feb. 18, 2000 (DE) 100 07 476.6

(51) Int. Cl. H03B 1/00

(52) U.S. Cl. 327/552

(57) ABSTRACT

The subject of this invention is a filter circuit, designed especially for the separation of two channels, with a low-pass filter (10, 14) and an additional all-pass filter (12).

This invention refers to an electronic filter circuit designed especially for the separation of two channels with a low-pass filter that is designed preferably as a Chebyshev filter.

### BACKGROUND OF THE ART

Filter circuits of this type are well known. They are used in stereo transmitters for the transmission of spatial sound signals. Stereo transmitters transmit a mono-signal, which contains a complete sound impression—so that a mono-signal can be reproduced in a monophonic form—and a second signal, which, as the so-called auxiliary signal, together with the mono-signal, makes possible a spatial impression of the sound signal.

The auxiliary signal is shifted by 38 kHz in relation to the mono-signal by modulating it upon a subcarrier frequency voltage of a frequency of 38 kHz with a resulting amplitude-modulated signal. Before the transmission of the auxiliary signal, the subcarrier frequency voltage is suppressed. In this connection we wish to make a remark that an additional pilot voltage is transmitted for the purpose of recovering the subcarrier frequency voltage at the receiver's side. The pilot voltage frequency equals half of the subcarrier voltage frequency, i.e., the frequency of the pilot voltage is 19 kHz.

Furthermore, there is a stereo-coder, in which a multiplication with the 38 kHz auxiliary signal is performed.

The stereo-coder can include e.g. a rectifier modulator with diodes connected in ring for the suppression of the carrier voltage of the amplitude-modulated signal. The diodes are switched by the subcarrier frequency voltage. The generated amplitude-modulated signal is, among other things, transmitted to an output terminal through the switched-through diodes. At the exit of the rectifier modulator is generated an auxiliary signal, which contains only the two side oscillations. For the subcarrier frequency voltage to be able to switch the diodes, the subcarrier frequency voltage must be significantly higher than the voltage of the auxiliary signal. Therefore, the stereo transmitter works with a high operational voltage. However, since the diodes are not linear above the range of modulation, undesired non-linear distortion arises.

As an alternative, analog multipliers—designed especially as integrated circuits—can be used, which often include differential amplifiers consisting of six transistors (the so-called Gilbert cells) with small modulations. However, the disadvantage of this solution includes temperature drift, non-linear distortion and insufficient signal-to-noise spacing due to the very small modulations of the semiconductor characteristics.

Finally, stereo-coders also exist that scan the signal to be transmitted, the signal containing a mono signal, a pilot signal and an auxiliary signal. The scanning of the signal to be transmitted is performed by an electronic switch that switches periodically. In the switch position “ON”, a capacitor is charged to the instantaneous value of the signal. In the switch position “OFF”, the capacitor holds the previously scanned signal voltage and transfers it to an amplifier with a high-impedance input. If the scanned frequency is smaller than the double of the frequency of the highest partial oscillation of the signal to be transmitted, a signal of a lower frequency (alias frequency signal) arises, and the signal to be transmitted cannot be faithfully recovered. In order to prevent an undesired signal distortion, the stereo-coder includes a low-pass filter (anti-alias filter), which cuts off the signal band. Depending on the particular design, a stereo-coder with a low-pass filter must be balanced/gauged, is dependent on temperature, and is expensive to construct. Therefore, such a switch-coder performs the multiplication with a 38 kHz square-wave signal and not with a sinusoidal signal. The signal amplitudes can represent not only a few milli-volts as with a rectifier modulator or an analog multiplier, but advantageously also several volts, which allows achieving excellent signal-to-noise spacing. Another advantage is that there basically arise no non-linear distortions because no non-linear components are used since the electronic switches are “ideal” to such degree.

The switched 38 kHz signal consists of dominant waves and harmonic waves. However, the harmonic waves are a disturbance since they reduce the channel separation of the transmitted stereo signals during the demodulation by a receiver. Therefore, a filter circuit is required with a pass-band width, within which the transmitted signal passes as much frequency-independent and undistorted as possible, while the disturbing harmonic oscillation is suppressed as much as possible.

The known filter circuits according to Chebyshev and the known filter circuits according to Butterworth show a strong frequency-dependent group retardation in the pass-band range. The known filter circuits according to Bessel show a very uneven attenuation in the pass-band range.

An object of this invention is to design a filter circuit especially for a stereo-coder that is especially suitable for the transmission of sound signals, and in which the disadvantages of the known circuit arrangements, especially a frequency-dependent group retardation and an uneven attenuation in the pass-band range, are prevented.

### SUMMARY OF THE INVENTION

According to this invention, this task relating to the filter circuit of the previously described type is resolved in such a manner that an all-pass filter is added.

Compared to the current state of technology, the filter circuit designed according to this invention can achieve, in a relevant pass-band range, a highly even attenuation and group retardation, i.e., an approximately linear amplitude characteristic and an approximately linear phase characteristic. Using the filter circuit designed according to this invention, stereo-coder can be constructed on the switching principle, with an extraordinary large signal-to-noise spacing with a low distortion and without any balancing. Therefore, the filter or filter circuit designed according to this invention is suitable for the attenuation of harmonic waves that arise in the switch of the stereo-coder due to the switching operations. The filter according to this invention is especially suitable to effectively suppress harmonic waves of the third and fifth order outside the pass-band range, namely in the stop range of the filter, and to guarantee a high-frequency band width of the signal that complies with the strict requirements of the regulating agencies such as the European Telecommunication Standard Institute (ETSI).

The all-pass filter can be connected to the output of the low-pass filter. However, it is also possible that the low-pass filter include a filter order low-pass, typically passive, which is connected between the input of the filter circuit and the all-pass filter, and possibly also an additional low-pass of the first or higher order, which is connected to the output of the all-pass filter. Such a circuit design could be advantageous to the extent as the (normally negligible) noise of the all-pass filter is eliminated by the subsequent low-pass.

One embodiment teaches the connection of a passive RC low-pass to the input of the invention-related filter circuit in order to reduce the band width and the rise speed of the slopes of the input signal, and the all-pass filter is connected on the output side of the low-pass filter. This design version of the filter circuit prevents rise distortions, which would normally develop if the signal is generated by an analogue switch with steep signal slopes and transferred to an operational amplifier.

In one of the design versions, at least two pole points of the filter circuit are in the stop range, preferably at the frequencies to be attenuated, especially with harmonic waves of the scanned frequency and/or the frequencies of the sidebands of the scanned frequency.

In some embodiments, the low-pass filter will consist of a first low-pass filter of the first order and a subsequently connected low-pass filter preferably of the fifth order. Such a low-pass filter shows a relatively low portion of standing waves so that the signal amplitude in the pass range is especially even. The filter circuit includes a filter terminal impedance connected between the output of the low-pass filter and the ground.

In many embodiments, the low-pass filter is an active RC low-pass filter. Furthermore, the filter terminal impedance is possibly designed as a capacitor. This design version of the invention minimizes the number of inductive components. Inductive components such as coils are relatively more costly than ohmic resistors and capacitors. Since many embodiments of the invention will minimize the number of inductances, the cost of such a circuit is especially low.

In many embodiments of the invention, the low-pass filter comprises in-series connected resistors and two frequency-dependent negative resistors (FDNR), which are connected between the connection points of the resistors and the ground.

If the all-pass filter is designed as an all-pass filter of the first order, the design version is especially simple. The all-pass filter is preferably designed as an active RC all-pass filter. The active RC all-pass filter can be economically manufactured without any inductive components, especially without any coils.

In many embodiments, a first or a second trap amplifier is incorporated between the input of the invention-related filter circuit and the input of the low-pass filter as well as possibly between the output of the low-pass filter and the output of the filter circuit, particularly between the output of the low-pass filter and the input of the all-pass filter. Due to the first trap amplifier, the components of the input low-pass can be of high impedance and, therefore, can be kept small. The second trap amplifier makes a low-resistance dimensioning of the all-pass circuit possible, so that the resistors of the all-pass circuit emit only a low noise, and the capacitor's capacitance can be dimensioned relatively big and, therefore, simply and relatively precisely. In this design version, the all-pass filter circuit guarantees a flat frequency characteristic.

Additional embodiments of this invention are characterized in the related claims.

### BRIEF DESCRIPTION OF THE DRAWINGS

The following text describes in more detail design examples of this invention based on drawings, in which:

FIG. 1 shows a circuit diagram illustrating the design principle of the filter according to this invention; and

FIG. 2 shows a design version of the filter according to this invention with frequency-dependent negative resistors.

### DETAILED DESCRIPTION OF THE INVENTION

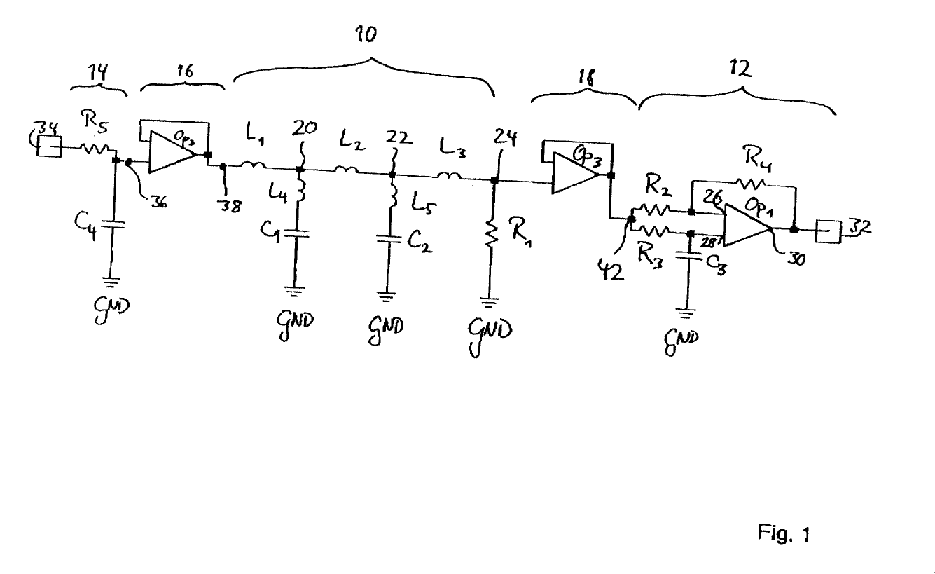

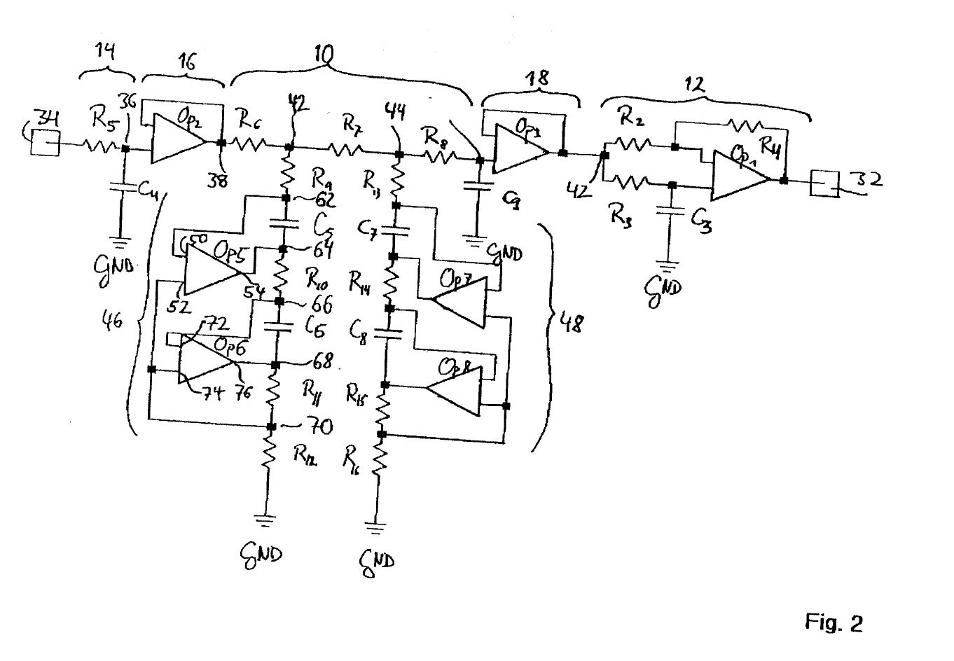

The filter shown in FIGS. 1 and 2 comprises a first circuit section 10 that is designed as a low-pass filter of the fifth order, as well as a second circuit section 12 that is designed as an all-pass filter of the first order. The all-pass filter 12 is connected at the output side of the fifth-order low-pass filter 10. A first-order low-pass filter 14 is connected on the input side of the fifth-order low-pass filter 10. Trap amplifiers 16,18 are connected between the output of the first-order low-pass filter 14 and the input of the fifth-order low-pass filter 10, and between the output of the fifth-order low-pass filter 10 and the input of the all-pass filter 12, respectively.

The low-pass filter 10 of the fifth order is designed as an in-series circuit of three coils L₁, L₂, L₃. The connection points 20, 22 between the coils L₁ and L₂ as well as L₂ and L₃ are connected with the ground GND through a series oscillatory circuit, which comprises a coil L₄ and a coil L₅ as well as a capacitors C₁ and C₂. The output 24 of the low-pass filter 10 is terminated in the ground GND by means of a resistor R₁.

The all-pass filter 12 comprises three resistors R₂, R₃, R₄, a capacitor C₃ as well as an operational amplifier Op₁. Both the resistor R₂ and the resistor R₃ are connected at the input 42 of the all-pass filter 12. The resistor R₂ is connected with the inverting input 26 and the resistor R₃ is connected with the non-inverting input 28 of the operational amplifier Op₁. The resistor R₄ forms a feedback between the output 30 of the operational amplifier Op₁ and its inverting input 26, while the non-inverting input 28 of the operational amplifier Op₁ is, in addition, connected to the ground GND through the capacitor C₃. The third resistor R₄ as well as the output 30 of the operational amplifier are connected to the output 32 of the all-pass filter 12.

The low-pass filter 14 of the first order comprises a resistor R₅, which is located between the input 34 of the circuit and a capacitor C₄ connected to the ground GND. In this way, the input of the low-pass filter 14 simultaneously forms the input 34 of the circuit, and the connection points of the resistor R₅ and the capacitor C₄ form the output 36 of the low-pass filter 14.

The trap amplifier 16 comprises an operational amplifier Op₂, and is connected between the output 36 of the low-pass filter 14 and the input 38 of the low-pass filter 10 in such a manner that the non-inverting input of the operational amplifier Op₂ is connected to the output 36 of the low-pass filter 14, and the output of the operational amplifier Op₂ is coupled as a feedback to its inverting input. Furthermore, the output of the operational amplifier Op₂ is connected to the input 38 of the low- pass filter 10.

The second trap amplifier 18 comprises an operational amplifier Op_{3.} The non-inverting input of the operational amplifier Op₃ is connected to the output 24 of the low-pass filter 10, while the output of this operational amplifier Op₃ is coupled as a feedback to its inverting input.

Furthermore, the output of the operational amplifier Op₃ is connected to the input 42 of the all- pass filter 12.

The low-pass filter 14 reduces the rise speed of the slope especially with impulse signals and thus prevents rise distortions that would normally arise when driving an amplifier with such signals. The first trap amplifier 16 provides, independent from the frequency, an output resistance of zero Ohm. The first trap amplifier 16 allows the second low-pass filter 14 to be dimensioned with high-impedance. Due to the second trap amplifier 18, which is connected at the output side of the first low-pass filter 10 and has the same design as the first trap amplifier 16, the all-pass filter 12, which is connected at the output side of the second trap amplifier 18, can be dimensioned with low resistance, which minimizes the disadvantageous effects of resistor noise and capacitor tolerances.

The circuit arrangement according to this invention illustrated in FIG. 2 differs from the circuit arrangement illustrated in FIG. 1 in that the low-pass filter 10 is designed as an active low-pass filter that comprises a combination of operational amplifiers Op₄ to Op₇, resistors R₆ to R₈, R₉ to R₁₂ and R₁₃ to R₁₆, and capacitors C₅ to C₈. The resistors R₆ to R₇ and R₈ are connected in-series between the input 38 and the output 24 of the first low-pass filter 10. Frequency-dependent negative resistors 46 and 48 are connected to the connection points 43 and 44 between resistors R₆ and R₇ as well as R₇ and R₈ through a resistor R₉ and R₁₃, accordingly. Both frequency-dependent resistors 46 and 48 are connected against ground. Each of the two frequency-dependent negative resistors 46 and 48 comprises a series connection consisting of a first capacitor C₅ and C₇, a first resistor R₁₀ and R₁₄, a second capacitor C₆ and C₈, a second resistor R₁₁ and R₁₅, and a third resistor R₁₂ and R₁₆, as well as of two operational amplifiers Op₅ and Op₆ and Op₇ and Op₈.

The inverting input 50 of the first operational amplifier Op₅ is connected to the connecting point 62 between resistor R₉ and the first capacitor C₅. The non-inverting input 52 of the first operational amplifier Op₅ is connected to the connecting point 70 between the second resistor R₁₁ and the third resistor R₁₂. The output 64 of the operational amplifier Op₅ is connected to the connecting point 64 between the first capacitor C₅ and the first resistor R₁₀. The inverting input 72 of the second operational amplifier Op₆ is connected to the connecting point 66 between resistor R₁₀ and the second capacitor C₆ The non-inverting input 74 of the operational amplifier Op₆ is connected to the connecting point 70 between the second resistor R₁₁ and the third resistor R₁₂. The output 76 of the operational amplifier Op₆ is connected to the connecting point 68 between the second capacitor C₆ and the second resistor R₁₁.

The frequency-dependent negative resistor 48 has an analog circuit design.

According to the described design example, the low-pass filter 14 and low-pass filter 10 together form a low-pass of the sixth order. The low-pass filter 14 of the first order, which is connected after the input 34, is designed to reduce or eliminate slewing distortions, and the low-pass filter 10 performs the additional five orders, e.g. by means of frequency-dependent negative resistors as shown in the circuit arrangement illustrated in FIG. 2.

In an especially preferred design version as shown in the circuit design illustrated in FIG. 2, the circuit elements have the following values:

| Index | R/Ω | C/pF |
|---|---|---|
| 1 | — | — |
| 2 | 2210 | — |
| 3 | 2370 | 1000 |
| 4 | 2210 | 47 |
| 5 | 22186 | 1000 |
| 6 | 1850 | 1000 |
| 7 | 2870 | 1000 |
| 8 | 402 | 1000 |
| 9 | 1050 | 1000 |
| 10 | 2320 | — |
| 11 | 2260 | — |
| 12 | 4750 | — |
| 13 | 432 | — |
| 14 | 2050 | — |
| 15 | 2210 | — |
| 16 | 5110 | — |

The dimensioning of the circuit elements in the circuit according to this invention is not restricted to the aforementioned example. On the contrary, additional advantage of this invention can be achieved by combining the circuit elements and their values.

What is claimed:

1. A filter circuit comprising a low-pass filter and an additional all-pass filter.

2. The filter circuit of claim 1, wherein the all-pass filter is connected to an output of the low-pass filter.

3. The filter circuit of claim 2, wherein the filter circuit has at least two pole points in the stop range, preferably at the frequencies to be attenuated.

4. The filter circuit of claim 2, wherein the low-pass filter comprises a first-order low-pass filter connected to an input of the filter circuit.

5. The filter circuit of claim 4, wherein the first-order low pass filter is a passive filter.

6. The filter circuit of claim 5 wherein the fifth-order low pass filter is located subsequent to the first-order low-pass filter.

7. The filter circuit of claim 8, wherein the low-pass filter further comprises a fifth-order low pass filter.

8. The filter circuit of claim 2, further comprising a filter terminal impedance which grounds the output of the low-pass filter.

9. The filter circuit of claim 8, wherein the low-pass filter is an active resistance-capacitance (“RC”) low-pass filter, and the filter terminal impedance is a capacitance.

10. The filter circuit of claim 9, wherein the low-pass filter comprises a plurality of resistors connected in series, with a frequency-dependent negative resistor (“FDNR”) serving to ground a connection point between each of the plurality of resistors.

11. The filter circuit of claim 10, wherein each said frequency-dependent negative resistor further comprises:
a first capacitor and a first resistor connected in series in conjunction with a first operational amplifier, wherein an inverting input of the first operational amplifier is connected to a first pole of the first capacitor and an output of the first operational amplifier is connected between a second pole of the first capacitor and the first resistor;
a second capacitor and a second resistor connected in series in conjunction with a second operational amplifier, wherein an inverting input of the second operational amplifier is connected to a first pole of the second capacitor and an output of the second operational amplifier is connected between a second pole of the second capacitor and the second resistor;
the first pole of the second capacitor connected in series to the first resistor; and
a non-inverting input of each of the first and second operational amplifiers is connected after the second resistor.

12. The filter circuit of claim 9, wherein the active RC low-pass filter is a second low-pass filter, located subsequent to a first low pass filter.

13. The filter circuit of claim 2, wherein the all-pass filter is a first-order all-pass filter.

14. The filter circuit of claim 2, wherein the all-pass filter is an active RC all-pass filter.

15. A filter circuit according to claim 14, wherein the active RC all pass filter comprises:
first, second and third resistors;
a capacitor; and
an operational amplifier;
wherein an input of the all-pass filter is connected to the first resistor and the second resistor; the first resistor is connected to an inverting input of the operational amplifier; the second resistor is connected to a non-inverting input of the operational amplifier; the third resistor is connected between the inverting input and the output (30) of the operational amplifier, and the capacitor is connected between the non-inverting input of the operational amplifier and the ground;
such that an output of the active RC all-pass filter forms the output of the filter circuit.

16. The filter circuit of claim 2, further comprising a trap amplifier connected between the low-pass filter and the all-pass filter.
